(19) United States
(12) Patent Application Publication
(10) Pub. No.: US 2021/0336123 A1
(43) Pub. Date: Oct. 28, 2021

(54) Area Element

(71) Applicant: Stefan Haas, Neufraunhofen (DE)

(72) Inventors: Stefan Haas, Neufraunhofen (DE); Rolf Schumacher, Balingen (DE)

(21) Appl. No.: 17/237,068

(22) Filed: Apr. 22, 2021

(30) Foreign Application Priority Data
Apr. 28, 2020 (DE) 102020111547.4

(51) Int. Cl. H01L 41/113; A41D 1/00; D03D 1/00

(52) U.S. Cl. CPC H01L 41/1132; D10B 2401/16; D03D 1/0088; A41D 1/005

(57) ABSTRACT

A surface element with a first layer, which has a conductive loop embedded in an insulating material, and with a sensor layer forming a second layer that is in contact with the conductive loop. The sensor layer is designed for detecting at least one external input variable. Dependent upon this detection, a current flowing through the conductive loop is affected. The surface element can be operated in a reverse operation such that by feeding currents into the conductive loop, the one or each of multiple sensor layer(s) generates output variables.

### CROSS REFERENCE TO RELATED APPLICATIONS

This application claims the priority of DE 102020111547.4 filed on Apr. 28, 2020; this application is incorporated by reference herein in its entirety.

### BACKGROUND

The invention relates to a surface element.

Such surface elements can be formed as textile surfaces, for example. These textile surfaces can be equipped with conductive threads by means of which sensor functions are provided.

In WO 2018/113993 A1, a method is disclosed in which sensor structures and cut-resistant structures are produced in a surface element by means of a warp knitting machine or Raschel machine. On the same side of the surface element, sensor threads are worked in as sensor structures and cut-resistant threads are worked in as cut-resistant structures. The sensor threads are optimized such that with them, easily verifiable electrical signals are generated, which signals can be evaluated in a measurement apparatus, in order that, in the event the sensor threads are cut, an alarm message or similar can be generated.

### SUMMARY

The invention relates to a surface element (1) with a first layer (2), which has a conductive loop (3) embedded in an insulating material, and with a sensor layer (5) forming a second layer that is in contact with the conductive loop (3). The sensor layer (5) is designed for detecting at least one external input variable. Dependent upon this detection, a current flowing through the conductive loop (3) is affected. The surface element (1) can be operated in a reverse operation such that by feeding currents into the conductive loop (3), the one or each of multiple sensor layer(s) (5) generates output variables.

### DETAILED DESCRIPTION

The invention seeks to solve the problem of providing a surface element with expanded functionality.

To solve this problem, the features of claim 1 are provided. Advantageous embodiments and expedient further developments of the invention are described in the dependent claims.

The invention relates to a surface element with a first layer that has a conductive loop embedded in an insulating material and with a second layer forming a sensor layer that is in contact with the conductive loop. The sensor layer is designed to detect at least one external input variable. A current flowing through the conductive loop is affected depending on this detection. In reverse operation, the surface element can be operated such that by feeding current into the conductive loop, the or each sensor layer generates output variables.

The basic idea of the invention therefore consists in having the sensor layer form a flat sensor element, preferably one that extends over the entire area of the surface element, by means of which sensor element external input variables can be registered with a high degree of sensitivity, according to the first variant of the invention.

According to another alternative, the sensor layer can be used to generate specific output variables when the surface element is operated in reverse operation.

The external input variables cause changes of status values in the sensor layer, which causes a change in the current (i.e. in general, in the electrical current) in the conductive loop, since the conductive loop is in contact with the sensor layer.

By time-resolved evaluation of the current in the conductive loop, it is not only possible to determine time dependencies of an external input variable; rather, in this manner, two or even more external input variables detected simultaneously with the sensor layer can be differentiated from one another if they have sufficiently different behavior over time.

This is the case, for example, if the sensor layer is a conductive layer. The conductive layer is designed for detecting mechanical loads and/or for detecting environmental moisture.

While mechanical loads cause short-term changes in the current in the conductive loop, the influence of environmental moisture causes a change of the current in the conductive loop that is nearly constant over time. By performing a time-resolved evaluation of the current in the conductive loop, both input variables can be detected separately. Depending on the application case, the time-resolved evaluations can be attributed to an input variable. For example, mechanical loads cause long-term change in input variables, while conversely, moisture causes a short-term change in input variable.

Alternatively, the sensor layer can be a piezoelectric layer. The piezoelectric layer is designed for detecting mechanical loads.

Therefore in this case, only one external input variable is detected by evaluating the current in the conductive loop.

Advantageously, both sides of the surface element can be covered with an insulating layer, which serves to protect the sensor structures.

In general, the first and second layer can be formed by a common surface element or by two separate surface elements.

For example, a single surface segment in the form of a foil or similar can be provided, in which both the conductive loop as well as the sensor layer can be integrated.

For the case that the first and second layers form separate surface segments, it is advantageous for the first layer to be a textile layer, wherein the conductive loop is provided on the side of the first layer facing toward the sensor layer.

For example, the textile surface is a woven, flat-knitted, warp-knitted or nonwoven fabric.

It is then advantageous for the conductive loop to be worked into the textile surface in the form of electrically conductive threads.

The working in can then be performed by means of suitable textile machines capable of performing weaving, warp knitting, flat knitting or similar processes.

Other methods can be used to produce the conductive loop as well, such as printing methods, for example.

It is advantageous for the sensor layer to be applied to the first layer as a coating.

According to an advantageous further development, an adaptation layer is provided on the side of the first layer opposite the sensor layer.

The adaptation layer consists of an insulating or weakly conductive material.

In particular, the adaptation layer forms an application-specific adaptation to different media onto which the surface element is applied.

According to an advantageous alternative further development of the invention, a conductive loop is provided respectively on opposite sides of the first layer, wherein each conductive loop is in contact with a sensor layer.

Thereby two sensor layers are available by means of which, advantageously, different external input variables can be detected. There is another essential advantage here insofar as a separate conductive loop is associated with each sensor layer, such that with these conductive loops, the external input variables can be detected separately and independently from one another.

According to an alternative embodiment of the invention, the sensor layer is integrated in the conductive loop.

For example, the conductive loop is formed by electrically conductive threads, which together with sensor threads form interwindings, wherein the sensor threads form the sensor layer.

Due to the fact that the conductive threads and sensor threads interwind, they are mechanically in contact with one another.

Therefore, changes in the sensor threads caused by external input variables can be directly transmitted to the electrically conductive threads forming the conductive loop, by means of which the current in the conductive loop changes and therefore the external input variable is detected by measurements.

For example, the sensor threads are formed from piezoelectric threads.

Mechanical loads affecting the surface element are detected with these sensor threads.

Especially advantageously, a network of piezoelectric threads onto which a conductive loop is integrated can be provided as a sensor layer.

In general, the output signals of the [one], or each, conductive loop form a measure for external input variables.

The surface elements according to the invention can be used in various applications.

In particular, the surface elements can be laid in floors or walls of buildings. In particular, continuous moisture monitoring can be implemented in bathrooms. The surface elements can form sleeves of conduits or pipes in which fluids such as oil, water or toxic substances are transported. An uncontrolled emergence of fluid can be detected with the surface element. Mechanical loads can be detected as well by surface elements on floors. Additional applications include determining the weight of pallets, containers and similar. Impact effects of shots fired at protective vests equipped with the surface element can also be analyzed.

Moreover, outdoor applications, such as on terraces or balconies of buildings are possible.

Finally, applications in motor vehicles, such as on loading beds of trucks, are possible.

According to the second variant of the invention, the surface element according to the invention can also be operated in reverse operation such that by feeding currents into the conductive loop, the [one], or each, sensor layer generates output variables.

For example, light radiation or a heat emission are provided as output variables.

According to an especially advantageous embodiment, the surface element has two first layers, each with a conductive loop embedded in an insulating material. Between the first layers, a sensor layer is provided, which in reverse operation of the surface element can generate output variables.

An advantageous embodiment in this regard is the production of electrical fields when the conductive loops are arranged such that two layers with opposite charges result.

Magnetic fields can also be produced by the surface element in reverse operation.

By applying a voltage, the sensor layer can influence electrochemical processes. External input variables that are a component of these processes can both be introduced from the exterior as well as be stored within the sensor layer.

In a first application case, the surface element can have a self-disinfecting effect. The surface element can then be used as a protective mask. Also, the surfaces of everyday objects installed in public areas, in particular, can be clad with the surface element, which due to its self-disinfecting effect is self-cleaning. Examples of this include park benches, etc.

Laborious cleaning and/or disinfection processes for these objects are then rendered unnecessary.

Such objects equipped with the surface elements according to the invention can advantageously be used for application areas in which persons often come into contact with the objects.

Examples of such application areas are public buildings and facilities, hospitals, public transportation, hotels and offices.

Objects equipped with the surface elements according to the invention can be door handles, door frames, walls or other everyday items such as tablets, carts or seat covers. Clothing can also be equipped with the surface elements, especially police, paramedic or military clothing.

The functioning of the surface element is then such that the sensor layer is an electrically insulating layer or membrane in which, in the presence of a voltage at the conductive loops, reactive oxygen compounds are generated.

The first layers can be formed analogous to the way the surface elements are formed according to the first variant of the invention. In particular, the first layers can be formed as textile layers. The conductive loops can be worked into the textile surfaces in the form of electrically conductive threads. Alternatively, the conductive loops can be formed by printing or coating.

The electrically insulating sensor layer can be formed as a foil, coating or similar. It is especially advantageous for the sensor layer to consist of a nonwoven or similar textile surface. It is advantageous for the sensor layer to form a porous, electro-osmotic layer. Together with water, moisture or oxygen, reactive oxygen species (ROS) are formed when a voltage is applied to the conductive loops, which ROS can damage pathogens such as viruses or bacteria. Oxygen peroxide is one example of an ROS.

Another application case can result insofar as the sensor layer is an electrically insulating layer, in which, depending on the presence of a voltage at the conductive loop, an ion structure is changed as an output variable by the force effects from the sensor layer. Then depending on the status of the output variable, the sensor layer is air-permeable or air-impermeable.

In both variants of the surface element according to the invention, the surface element can be covered on both sides with an insulating layer.

To realize especially large-format structures, a multiple arrangement with multiple adjacent, connecting surface elements can be provided, wherein the conductive loops of the individual surface elements are then conductively connected to one another.

### BRIEF DESCRIPTION OF THE DRAWINGS

The invention is explained below based on the drawings. They show:

FIG. 1: First exemplary embodiment of the surface element according to the invention.

FIG. 2: Individual depiction of components of the surface element from FIG. 1.

FIG. 3: Second exemplary embodiment of the surface element according to the invention.

FIG. 4: Individual depiction of components of the surface element from FIG. 3.

FIG. 5: Additional exemplary embodiment of the surface element according to the invention.

### DETAILED DESCRIPTION OF THE PREFERRED EMBODIMENTS

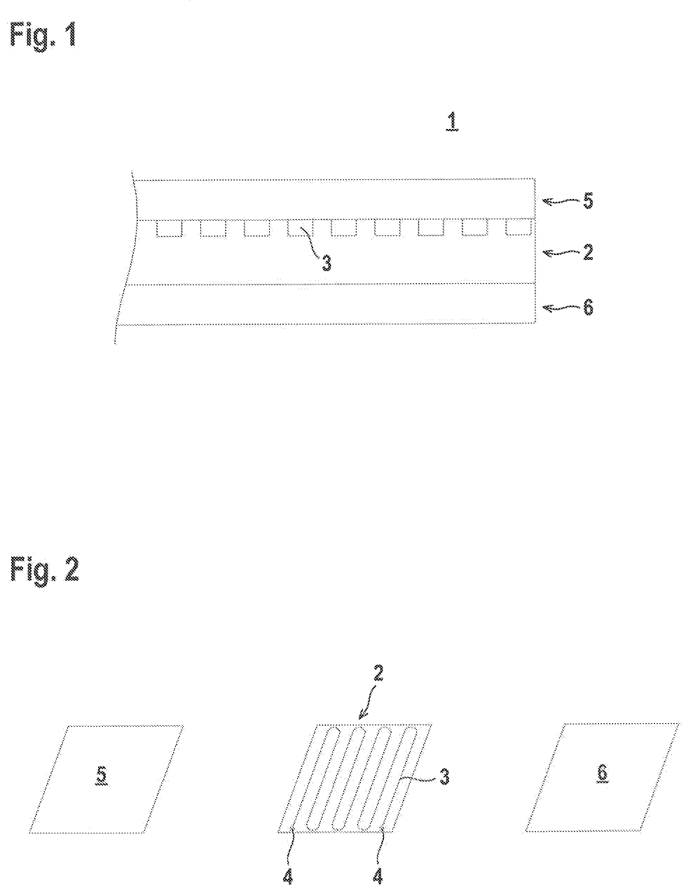

FIG. 1 shows a first exemplary embodiment of the surface element 1 according to the invention, wherein its components are individually depicted in FIG. 2.

The surface element 1 according to FIGS. 1 and 2 has a first layer 2 that is generally composed of an insulating, i.e. non-conductive, material, wherein in this layer a conductive loop 3 made of an electrically conductive material is provided.

In the present case, the first layer 2 is composed of a textile surface that is built up from insulating threads or yarns.

For example, the textile surface is a woven, flat-knitted, warp-knitted or nonwoven fabric.

In the present case, the conductive loop 3 is worked into the textile surface in the form of electrically conductive threads.

As is evident in FIG. 2, the conductive loop 3 extends across the entire surface of the first layer 2, wherein the loop runs through multiple loops in a meander pattern.

At an edge of the first layer 2, the free ends of the conductive loop 3 open out to form measuring points 4 at which a measurement device, especially a current measuring device, can be connected.

In the present case, the measuring points 4 open out on the same edge of the first layer 2. In general, the two measuring points 4 can open out on different edges, especially opposing edges.

The second layer forms a sensor layer 5, by means of which one or multiple external input variables can be detected. Preferably the entire surface of the sensor layer 5 forms a surface that is sensitive for detecting the variables.

In the present case, the sensor layer 5 is formed in the form of a coating that is applied to the first layer 2. In principle, the first and second layer can also form a common surface segment, such as in the form of a foil.

The sensor unit can be formed from a piezoelectric layer.

In the present case, the sensor layer 5 is formed in the form of an electrically conductive layer. It is essential, as is evident in FIG. 1, for the conductive layer, i.e. the sensor layer 5, to be in contact with the conductive loop 3 of the first layer 2.

Changes in the (electrical) conductivity therefore directly affect the current in the conductive loop 3, which is immediately registered by measurements at the measuring points 4.

Using the conductive sensor layer 5, two external input variables can be detected, namely on the one hand, the environmental moisture affecting the conductivity and on the other hand, mechanical loads that result in local deformations of the sensor layer 5 and as a result, to current changes in the conductive loop 3.

The two variables can be detected separately in a suitable evaluation unit by a time-resolved detection of the current in the conductive loop 3. In this manner, static changes of the current in the conductive loop 3 caused by the environmental moisture can be reliably differentiated from dynamic current changes that vary more significantly over time in the conductive loop 3 caused by mechanical influences. The attribution of the current change can vary based on the application case.

The third layer of the surface element 1 from FIG. 1 forms an adaptation layer 6, which is designed especially for an adaptation of the surface element 1 to different supporting materials.

It is advantageous for the adaptation layer 6 to be made of an insulating or weakly conductive material.

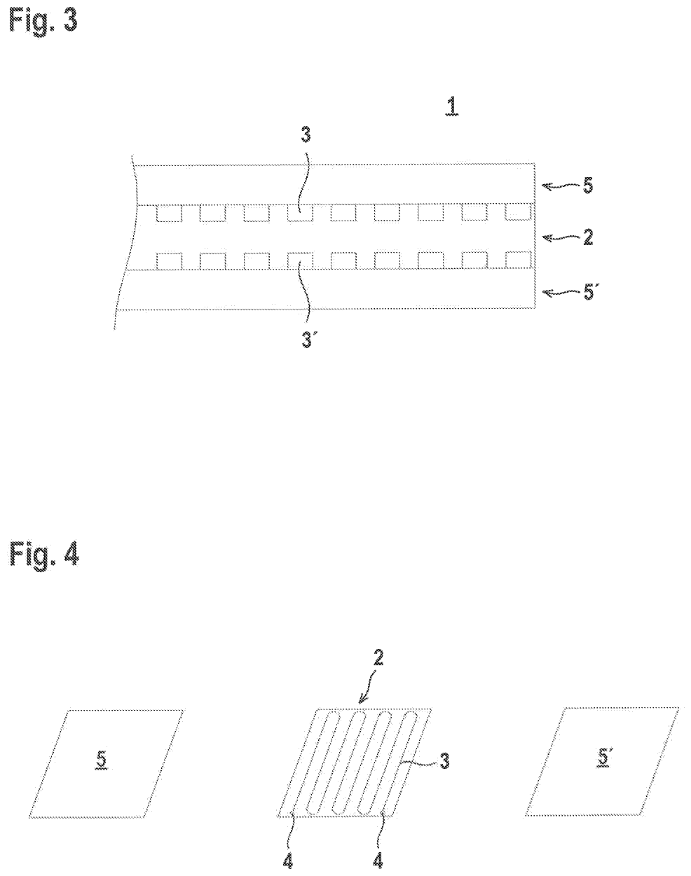

FIG. 3 shows a second exemplary embodiment of the surface element according to the invention.

In the embodiment from FIG. 3, a sensor layer 5, 5′ is provided respectively at opposing sides of the first layer 2.

In the first layer 2, respectively on opposing sides, there is a conductive loop 3, 3′ that is respectively in contact with a sensor layer 5, 5′.

Analogous to the embodiment, the first layer 2 is composed of a textile surface in which the conductive loops 3, 3′ are worked in.

In principle, the sensor layers 5, 5′ can be identical in form.

In the present case, different sensor layers 5, 5′ are provided that detect different variables. The first sensor layer 5 can be formed as a conductive layer. By evaluating the current in the associated conductive loop 3, the environmental moisture, for example, can be detected. The second sensor layer 5′ can be formed from a piezoelectric layer. By evaluating the current in the associated conductive loop 3′, mechanical loads that affect the surface element 1 are detected.

In both embodiments of the surface element 1, the latter can be covered on both sides with an insulating layer.

These insulating layers are not depicted in FIGS. 1 and 2.

In general, multiple surface elements 1 according to FIG. 1 or 2 can be joined together to form a large, continuous surface. In this case, the ends of the conductive loops 3 of adjacent surface elements 1 are connected together.

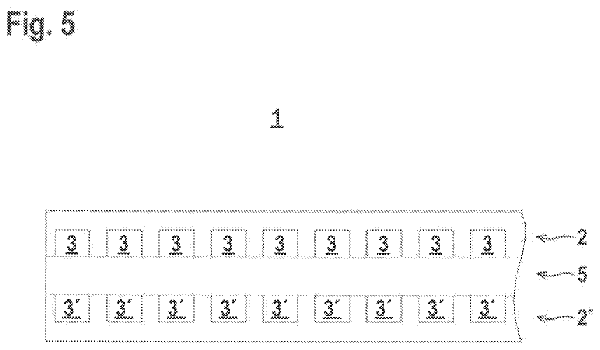

FIG. 5 shows another exemplary embodiment of the surface element 1 according to the invention, wherein in the present case, it is operated in reverse operation, such that defined output variables can be generated with its sensor layer 5.

The sensor layer 5 lies between two first layers 2, 2′ with respectively one conductive loop 3, 3′. The first layers 2, 2′ are composed of textile surfaces. The conductive loops 3, 3′ can be formed from electrically conductive threads that are worked into the textile surfaces. The conductive loops 3, 3′ can be connected to a voltage source, such as a battery. The conductive loops 3, 3′ can be designed such that two layers with opposite charges result.

The sensor layer 5 is an electrically insulating layer that, in principle, can be formed in the form of a foil or coating. The sensor layer 5 is preferably a porous, electro-osmotic layer, such as a nonwoven. When introducing a voltage to the conductive loops 3, 3′, an electrical and/or magnetic field is produced in the sensor layer, by means of which field a potential for the surface element can arise. Together with external input variables such as moisture/water and oxygen, in this manner reactive oxygen species (ROS), which can damage viruses or bacteria, can arise. In this regard, in other embodiments, the required input variables for the desired electrochemical reaction can also be stored for the short-term or long-term in the sensor layer 5.

### LIST OF REFERENCE NUMERALS

(1) Surface element

(2) Layer, first

(3, 3′) Conductive loop

(4) Measuring point

(5, 5′) Sensor layer

(6) Adaptation layer

1. A surface element (1) with a first layer (2) that has a conductive loop (3) embedded within an insulating material and with a second layer forming a sensor layer (5), which is in contact with the conductive loop (3), wherein the sensor layer (5) is designed for detecting at least one external input variable and dependent upon this detection, a current flowing in the conductive loop (3) is affected, or that the surface element (1) is operated in a reversed operation such that by feeding currents into the conductive loop (3), the or each sensor layer (5) generates output variables.

2. The surface element (1) according to claim 1, characterized in that the first layer (2) and the second layer are formed from a common surface segment or from two separate surface segments.

3. The surface element (1) according to claim 1, characterized in that the first layer (2) is a textile surface, wherein the conductive loop (3) is provided on the side of the first layer (2) facing toward the sensor layer (5).

4. The surface element (1) according to claim 3, characterized in that the textile surface is a woven, flat-knitted, warp-knitted or nonwoven fabric.

5. The surface element (1) according to claim 3, characterized in that the conductive loop (3) is worked into the textile surface in the form of electrically conductive threads.

6. The surface element (1) according to claim 1, characterized in that the sensor layer (5) is applied to the first layer (2) as a coating.

7. The surface element (1) according to claim 1, characterized in that the sensor layer (5) is a conductive layer or a piezoelectric layer.

8. The surface element (1) according to claim 1, characterized in that the conductive layer is designed for detecting mechanical loads and/or for detecting environmental moisture.

9. The surface element (1) according to claim 1, characterized in that on the side of the first layer (2) opposite the sensor layer (5), an adaptation layer (6) is provided, wherein the adaptation layer (6) is composed of an insulating or weakly conductive material.

10. The surface element (1) according to claim 1, characterized in that a conductive loop (3, 3′) is respectively provided on opposite sides of the first layer (2), wherein each conductive loop (3, 3′) is in contact with a sensor layer (5, 5′).

11. The surface element (1) according to claim 1, characterized in that the sensor layer (5, 5′) is integrated in the conductive loop (3, 3′).

12. The surface element (1) according to claim 11, characterized in that the conductive loop (3, 3′) is formed by electrically conductive threads, which along with sensor threads form interwindings, wherein the sensor threads form the sensor layer, wherein especially the sensor threads are formed by piezoelectric threads.

13. The surface element (1) according to claim 1, characterized in that the output signals of the or each conductive loop (3, 3′) form a measure for external input variables.

14. The surface element (1) according to claim 1, characterized in that it has two first layers (2, 2′), each with a conductive loop (3, 3′) embedded in an insulating material, and that between the first layers (2, 2′), a sensor layer (5, 5′) is provided, which in reverse operation of the surface element (1) can generate output variables.

15. The surface element (1) according to claim 14, characterized in that the sensor layer (5, 5′) is an electrically insulating layer in which, in the presence of a voltage at the conductive loops (3, 3′), reactive oxygen compounds are generated.

16. The surface element (1) according to claim 15, characterized in that in the presence of a voltage at the conductive loops (3, 3′), electric and/or magnetic fields are generated.

17. The surface element (1) according to claim 14, characterized in that in the sensor layer (5, 5′), electrochemical processes are generated, through which input variables in the form of reactive oxygen compounds result.

18. The surface element (1) according to claim 17, characterized in that external input variables are stored in the sensor layer (5, 5′) for predetermined time periods.

19. The surface element (1) according to claim 14, characterized in that the sensor layer (5, 5′) is an electrically insulting layer in which, depending on the presence of a voltage at the conductive loops (3, 3′), an ion structure in the sensor layer (5, 5′) is changed, as an output variable, wherein depending on the status of the output variable, the sensor layer (5, 5′) is air-permeable or air-impermeable.

20. The surface element (1) according to claim 1, characterized in that light radiation or a heat emission are provided as output variables.
